(19) United States
(12) Patent Application Publication
(10) Pub. No.: US 2009/0140301 A1
(43) Pub. Date: Jun. 4, 2009

(54) REDUCING CONTACT RESISTANCE IN P-TYPE FIELD EFFECT TRANSISTORS

(76) Inventors: Mantu K. Hudait, Portland, OR (US); Marko Radosavljevic, Beaverton, OR (US); Suman Datta, Port Matilda, PA (US)

Correspondence Address: COOL PATENT, P.C.;c/o CPA Global, P.O. BOX 52050, MINNEAPOLIS, MN, 55402, US

(21) Appl. No.: 11/947,157

(22) Filed: Nov. 29, 2007

(51) Int. Cl. H01L 29/94; H01L 21/336

(52) U.S. Cl. 257/288; 438/197; 257/E21.409; 257/E29.345

(57) ABSTRACT

Reducing contact resistance in p-type field effect transistors is generally described. In one example, an apparatus includes a first semiconductor substrate, a first noble metal film including palladium (Pd) coupled with the first semiconductor substrate, a second noble metal film including platinum (Pt) coupled with the first noble metal film, and a third metal film including an electrically conductive metal coupled with the second noble metal film, wherein the first, second, and third metal films form one or more contacts having reduced specific contact resistance between the first semiconductor substrate and the one or more contacts.

### BACKGROUND

Generally, semiconductor devices have specific contact resistance between an electrically conductive contact and a semiconductor material.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 is a schematic diagram of one or more contact structures formed on a semiconductor material, according to but one embodiment;

FIG. 2 is a flow diagram of a method to reduce contact resistance, according to but one embodiment; and

FIG. 3 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of reducing contact resistance in p-type field effect transistors (PFET) are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

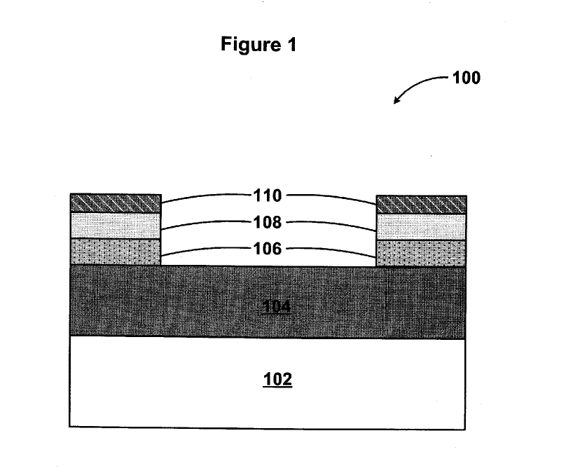

FIG. 1 is a schematic diagram of one or more contact structures formed on a semiconductor material 100, according to but one embodiment. In an embodiment, an apparatus 100 includes a generic substrate 102 representing a semiconductor substrate or stack of films or layers, a semiconductor layer or substrate 104, a first noble metal film 106, a second noble metal film 108, and a third metal film 110, each coupled as shown.

High speed and low power devices are being developed using low bandgap indium gallium arsenide (InGaAs) and related alloys. Like most high frequency devices, InGaAs-based high electron mobility transistors (HEMT) or heterojunction bipolar transistors (HBT) are susceptible to parasitic resistances. A primary source of such parasitic resistance may include metal/semiconductor contacts. The continuous scaling down of dimensions and the desire for high-frequency, high-speed performance for future generation devices may require lower specific contact resistance at the metal/semiconductor interface and improved thermal stability. Developing a reliable low-resistance ohmic contact to p-type InGaAs for source and drain in field effect transistor (FET) fabrication that simultaneously remains electrically and morphologically stable for the lifetime of the devices is a major challenge.

Solid-state reactions between contact metals and the semiconductors may form complicated microstructures as a result of thermal processing such as annealing. The ohmic contact may be solely determined by the interfacial microstructures, thus, the specific contact resistance may be reduced several order of magnitude by optimizing the thermal processing conditions as well as using a combination of contact metals to create low contact-resistance micro structures.

In an embodiment, an apparatus 100 includes a first semiconductor substrate 104, a first noble metal film 106 including palladium (Pd) coupled with the first semiconductor substrate 104, and a second noble metal film 108 comprising platinum (Pt) coupled with the first noble metal film 106. In another embodiment, an apparatus 100 includes a first semiconductor substrate 104, a first noble metal film 106 including Pt coupled with the first semiconductor substrate 104, and a second noble metal film 108 comprising Pd coupled with the first noble metal film 106. In an embodiment, a reduced specific contact resistance is achieved at the interface between the first noble metal 106 and first semiconductor 104 using a high work function metal for the first noble metal film 106, the first noble metal film including at least Pd and/or Pt, or suitable combinations.

In an embodiment, the second noble metal film 108 is coupled to the first noble metal film 106 using an annealing process that forms substantially no alloy between the first 106 and second 108 noble metal films. According to an embodiment, substantially no oxide forms at the interface between the first noble metal film 106 and the first semiconductor substrate 106. For example, substantially no oxide forms may include less than 1% oxide in one or more embodiments. In an embodiment, the thickness of the first noble metal film 106 is about 5 nm to 500 nm and the thickness of the second noble metal film 108 is about 5 nm to 500 nm.

In an embodiment, a first semiconductor substrate 104 includes a p-type semiconductor. The hole mobility for a P-channel FET may be low in comparison to an n-channel FET. For example, the barrier height for n-type InGaAs may be nearly zero and the barrier height for p-type InGaAs may be nearly the same as the entire band-gap, increasing the difficulty of forming low resistivity ohmic contacts for p-type material. In an embodiment, a semiconductor substrate 104 includes p-type InₓGa₁₋ₓAs, where x represents a value between about 0 and 1 to define the relative atomic amount of In and Ga in the first semiconductor substrate. In an embodiment, x represents a value between about 0.53 and 1. In an embodiment, p-type InₓGa₁₋ₓAs includes highly doped P⁺ or P⁺⁺InₓGa₁₋ₓAs. In an embodiment, a p-type semiconductor substrate 104 is doped with beryllium (Be), carbon (C), other p-type dopants, or suitable combinations thereof.

In an embodiment, the Schottky barrier height, φ_{b} between a p-type semiconductor 104 and a first noble metal film 106 may be the difference in their respective work functions, φₐ and φₘ:

φ_{b}=φₛ−φₘ (1)

In an embodiment, a first noble metal film 106 including high work function metals such as Pd and Pt may achieve lower specific contact resistance of p-type InₓGa₁₋ₓAs material for p-channel FETs compared with a first noble metal film 106 including titanium (Ti), for example. Ti may also adversely react with oxygen at the interface creating undesirable oxides or may form undesirable microstructures that increase specific resistance at the interface between a semiconductor material 104 and a contact metal 106, however the scope of the claimed subject matter is not limited in this respect.

An apparatus 100 may further include a third metal film 110 that includes an electrically conductive metal coupled with the second noble metal film 108. In an embodiment, the thickness of the third film is about 5 nm to 500 nm. In another embodiment, the first 106, second 108, and third 119 metal films form one or more contacts having reduced specific contact resistance between the first semiconductor substrate 104 and the one or more contacts. The one or more contacts may be ohmic contacts. In an embodiment, the third metal film 110 is coupled to the second noble metal film 108 using an annealing process that forms substantially no alloy between the second 108 and third 110 metal films. In another embodiment, the third metal film 110 comprises gold (Au), or copper (Cu), or suitable combinations thereof. In yet another embodiment, an apparatus 100 includes a non-alloyed Pd 106, Pt 108, Au 110 contact. A second noble metal film 108 including Pt may provide a suitable barrier film to prevent diffusion of Au 110.

An apparatus 100 may further include a second semiconductor 102 substrate or layer or stack of materials, layers, or films coupled with the first semiconductor 104 wherein the first semiconductor 104 is between the second semiconductor 102 and the one or more contacts 106, 108, 110. In an embodiment, the second semiconductor 102 includes InP or GaAs, or suitable combinations thereof. Semiconductor 102 may include semi-insulating InP or GaAs substrates.

In an embodiment, an apparatus 100 includes one or more p-channel transistor structures coupled with the one or more contacts 106, 108, 110 wherein the contacts are source/drain contacts of p-channel field effect transistor applications.

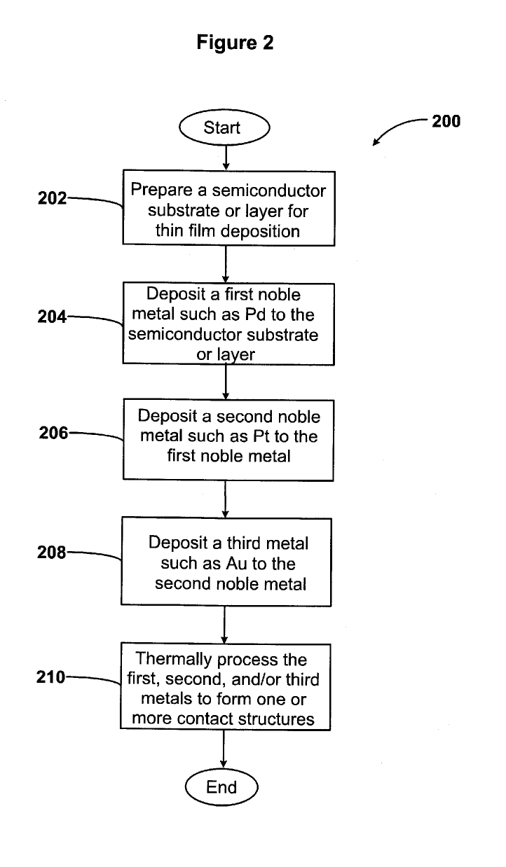

FIG. 2 is a flow diagram of a method to reduce contact resistance 200, according to but one embodiment. In an embodiment, a method 200 includes preparing a semiconductor substrate or layer for thin film deposition 202, depositing a first noble metal such as Pd to the semiconductor substrate or layer 204, depositing a second noble metal such as Pt to the first noble metal 206, depositing a third metal such as Au to the second noble metal 208, and thermally processing the first, second, and/or third metals to form one or more contact structures 210, with arrows providing only but one suggested flow.

Preparing a semiconductor substrate or layer for thin film deposition 202 at least includes cleaning the semiconductor surface upon which the thin film is to be deposited. In an embodiment, depositing a first noble metal 204 includes at least depositing Pd or Pt or suitable combinations thereof. In another embodiment, depositing a second noble metal 206 includes at least depositing Pd or Pt or suitable combinations thereof. A method 200 may further include depositing a third metal film to the second noble metal film 208, the third metal film including Au or Cu, or combinations thereof.

In an embodiment, thermally processing 210 includes annealing. In another embodiment, thermally processing 210 forms on or more contacts having reduced specific contact resistance between the semiconductor substrate and the one or more contacts. Thermal processing or annealing 210 may occur in other sequences than depicted in method 200. For example, thermally processing 210 may occur after depositing a first noble metal 204 and before depositing a second noble metal 206, according to an embodiment. In another embodiment, thermally processing 210 occurs after depositing a second noble metal 206 and prior to depositing a third metal 208. Various annealing temperatures or times may be used to anneal and/or bond the contact metals together. In an embodiment, an annealing temperature includes at least the temperature range from about 200° C. and 400° C. Annealing times may include at least a range from about 4 minutes to 20 minutes.

In an embodiment, thermally processing the first noble metal film, the second noble metal film, and the third metal film 210 includes annealing the first noble metal film to the second noble metal film to form substantially no alloy between the first and second noble metal films. In another embodiment, thermally processing 210 includes annealing the third metal film to the second noble metal film to form substantially no alloy between second and third metal films. According to an embodiment, annealing the first noble metal film to the second noble metal film and annealing the third metal film to the second noble metal film occurs simultaneously.

In an embodiment, depositing a first noble metal film including Pd to a semiconductor substrate 204 includes a semiconductor substrate including p-type InₓGa₁₋ₓAs where x represents a value between about 0.5 and 1 to define the relative atomic amount of In and Ga in the first semiconductor substrate. According to an embodiment, substantially no oxide forms at the interface between at least the first noble metal film and the first semiconductor substrate as a result of thermally processing 210 the first noble metal film, the second noble metal film, and the third metal film. In an embodiment where the first noble metal film includes Pd and the semiconductor substrate includes InₓGa₁₋ₓAs, Pd diffusion or a chemical compound such as Pd—As compound may form at the interface between the first metal Pd and InₓGa₁₋ₓAs interface due to annealing. Such reaction may provide a reduced interfacial contact resistance compared with a first noble metal including Ti. In an embodiment, higher annealing temperatures may adversely affect contact resistance due to In and Ga out-diffusion and Pd—As complex reactions forming various compounds such as PdₓAs_{y}, PdₓGa_{y}, or PdₓIn_{y}, where x and y represent suitable stoichiometric values. Such compounds may increase interfacial contact resistance between a first noble metal and semiconductor.

Depositing a first 204, depositing a second 206, and/or depositing a third film 208 includes depositing by e-beam deposition, physical vapor deposition (PVD), atomic layer deposition (ALD), chemical vapor deposition (CVD), sputtering, molecular beam epitaxy, or suitable combinations thereof. Other suitable methods for deposition may be used.

A method 200 may further include forming one or more p-channel transistor structures, the one or more p-channel transistor structures being coupled with the one or more contacts wherein the contacts are source/drain contacts of a p-channel field effect transistor application. A method 200 may incorporate embodiments already described with respect to FIG. 1.

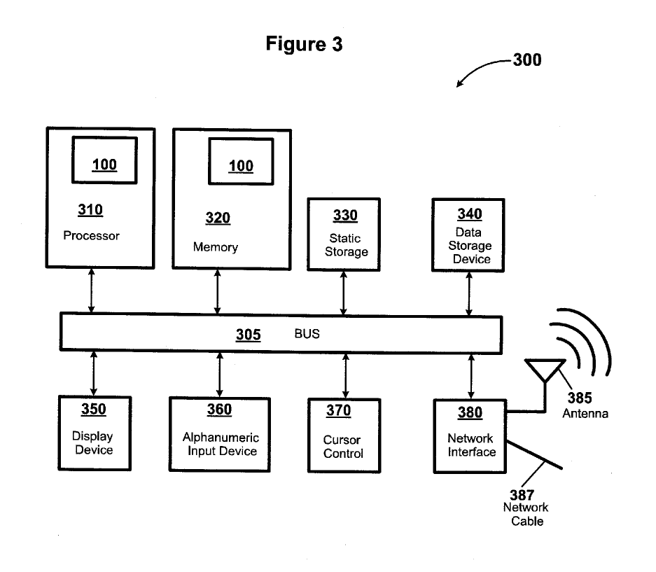

FIG. 3 is a diagram of an example system in which embodiments of the present invention may be used 300, according to but one embodiment. System 300 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 300 includes an apparatus having one or more contact structures 100 in accordance with embodiments described with respect to FIGS. 1-2. In an embodiment, an apparatus having one or more contact structures 100 as described herein is part of an electronic system's processor 310 or memory 320.

Electronic system 300 may include bus 305 or other communication device to communicate information, and processor 310 coupled to bus 305 that may process information. While electronic system 300 may be illustrated with a single processor, system 300 may include multiple processors and/or co-processors. In an embodiment, processor 310 includes an apparatus having one or more contact structures 100 in accordance with embodiments described herein. System 300 may also include random access memory (RAM) or other storage device 320 (may be referred to as memory), coupled to bus 305 and may store information and instructions that may be executed by processor 310.

Memory 320 may also be used to store temporary variables or other intermediate information during execution of instructions by processor 310. Memory 320 is a flash memory device in one embodiment. In another embodiment, memory 320 includes an apparatus having one or more contact structures 100 as described herein.

System 300 may also include read only memory (ROM) and/or other static storage device 330 coupled to bus 305 that may store static information and instructions for processor 310. Data storage device 340 may be coupled to bus 305 to store information and instructions. Data storage device 340 such as a magnetic disk or optical disc and corresponding drive may be coupled with electronic system 300.

Electronic system 300 may also be coupled via bus 305 to display device 350, such as a cathode ray tube (CRT) or liquid crystal display (LCD), to display information to a user. Alphanumeric input device 360, including alphanumeric and other keys, may be coupled to bus 305 to communicate information and command selections to processor 310. Another type of user input device is cursor control 370, such as a mouse, a trackball, or cursor direction keys to communicate information and command selections to processor 310 and to control cursor movement on display 350.

Electronic system 300 further may include one or more network interfaces 380 to provide access to network, such as a local area network. Network interface 380 may include, for example, a wireless network interface having antenna 385, which may represent one or more antennae. Network interface 380 may also include, for example, a wired network interface to communicate with remote devices via network cable 387, which may be, for example, an Ethernet cable, a coaxial cable, a fiber optic cable, a serial cable, or a parallel cable.

In one embodiment, network interface 380 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 380 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 300 includes one or more omnidirectional antennae 385, which may refer to an antenna that is at least partially omnidirectional and/or substantially omnidirectional, and a processor 310 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined entirely by the following claims, which are to be construed in accordance with established doctrines of claim interpretation.

What is claimed is:

1. An apparatus comprising:
a first semiconductor substrate;
a first noble metal film comprising palladium (Pd) coupled with the first semiconductor substrate;
a second noble metal film comprising platinum (Pt) coupled with the first noble metal film; and
a third metal film comprising an electrically conductive metal coupled with the second noble metal film, wherein the first, second, and third metal films form one or more contacts.

2. An apparatus according to claim 1 wherein the first semiconductor substrate comprises p-type InₓGa₁₋ₓAs where x represents a value between about 0.5 and 1 to define the relative atomic amount of In and Ga in the first semiconductor substrate and wherein substantially no oxide forms at the interface between the first noble metal film and the first semiconductor substrate.

3. An apparatus according to claim 1 wherein the third metal film comprises gold.

4. An apparatus according to claim 1 wherein the second noble metal film is coupled to the first noble metal film by an annealing process that forms substantially no alloy between the first and second noble metal films and wherein the third metal film is coupled to the second noble metal film by an annealing process that forms substantially no alloy between the second and third metal films.

5. An apparatus according to claim 1 wherein the one or more contacts are ohmic contacts.

6. An apparatus according to claim 1 wherein the thickness of the first noble metal film is about 5 nm to 500 nm, the thickness of the second noble metal film is about 5 nm to 500 nm, and the thickness of the third metal film is about 5 nm to 500 nm.

7. An apparatus according to claim 1 further comprising:
a second semiconductor substrate comprising InP or GaAs, or suitable combinations thereof, coupled with the first semiconductor substrate wherein the first semiconductor substrate is between the second semiconductor substrate and the one or more contacts; and
one or more p-channel transistor structures coupled with the one or more contacts wherein the contacts are source/drain contacts of a p-channel field effect transistor application.

8. A method comprising:
depositing a first noble metal film comprising palladium (Pd) to a semiconductor substrate;
depositing a second noble metal film comprising platinum (Pt) to the first noble metal film;
depositing a third metal film to the second noble metal film; and
thermally processing the first noble metal film, the second noble metal film, and the third metal film to form one or more contacts.

9. A method according to claim 8 wherein depositing a first noble metal film comprising Pd to a semiconductor substrate comprises depositing a first noble metal film comprising Pd to a semiconductor substrate, the semiconductor substrate comprising p-type InₓGa₁₋ₓAs where x represents a value between about 0.5 and 1 to define the relative atomic amount of In and Ga in the first semiconductor substrate and wherein substantially no oxide forms at the interface between at least the first noble metal film and the first semiconductor substrate as a result of thermally processing the first noble metal film, the second noble metal film, and the third metal film.

10. A method according to claim 8 wherein thermally processing the first noble metal film, the second noble metal film, and the third metal film comprises:
annealing the first noble metal film to the second noble metal film to form substantially no alloy between the first and second noble metal films; and
annealing the third metal film to the second noble metal film to form substantially no alloy between the second and third metal films.

11. A method according to claim 10 wherein annealing the first noble metal film to the second noble metal film and annealing the third metal film to the second noble metal film occurs simultaneously.

12. A method according to claim 8 wherein depositing a third metal film to the second noble metal film comprises depositing a third metal film comprising gold (Au) or copper (Cu), or combinations thereof, to the second noble metal film.

13. A method according to claim 8 wherein thermally processing the first noble metal film, the second noble metal film, and the third metal film to form one or more contacts comprises thermally processing the first noble metal film, the second noble metal film, and the third metal film to form one or more contacts wherein the one or more contacts are ohmic contacts.

14. A method according to claim 8 wherein depositing a first noble metal film comprising Pd to a semiconductor substrate comprises depositing a first noble metal film having a thickness between about 5 nm to 500 nm, depositing a second noble metal film comprising Pt to the first noble metal film comprises depositing a second noble metal film having a thickness between about 5 nm to 500 nm, depositing a third metal film to the second noble metal film comprises depositing a third metal film having a thickness between about 5 nm to 500 nm, and wherein depositing the first noble metal film, the second noble metal film, and third metal film comprises e-beam deposition, physical vapor deposition (PVD), atomic layer deposition (ALD), chemical vapor deposition (CVD), sputtering, molecular beam epitaxy, or suitable combinations thereof.

15. A method according to claim 8 further comprising:
forming one or more p-channel transistor structures, the one or more p-channel transistor structures being coupled with the one or more contacts wherein the contacts are source/drain contacts of a p-channel field effect transistor application.
